(19) United States
(12) Patent Application Publication
(10) Pub. No.: US 2020/0227239 A1
(43) Pub. Date: Jul. 16, 2020

(54) Electrostatic Shield for Inductive Plasma Sources

(71) Applicant: Mattson Technology, Inc., Fremont, CA (US)

(72) Inventors: Stephen Edward Savas, Pleasanton, CA (US); Chen-An Chen, San Jose, CA (US); Shawming Ma, Sunnyvale, CA (US)

(21) Appl. No.: 16/245,973

(22) Filed: Jan. 11, 2019

(51) Int. Cl. H01J 37/32

(52) U.S. Cl. CPC H01J 37/32174

(57) ABSTRACT

Electrostatic shields for inductive plasma sources are provided. In one implementations, a plasma processing apparatus can include a plasma chamber, a dielectric wall forming at least a portion of the plasma chamber, an inductive coupling element located proximate the dielectric wall. The inductive coupling element can generate a plasma in the plasma chamber when energized with radio frequency (RF) energy. The plasma processing apparatus can further include an electrostatic shield located between the inductive coupling element and the dielectric wall. The electrostatic shield can include a plurality of shield plates, slots, and/or layers.

### FIELD

The present disclosure relates generally to electrostatic shields for plasma processing apparatus and systems.

### BACKGROUND

Plasma processing tools can be used in the manufacture of devices such as integrated circuits, micromechanical devices, flat panel displays, and other devices. Plasma processing tools used in modern plasma etch and/or strip applications are required to provide a high plasma uniformity and a plurality of plasma controls, including independent plasma profile, plasma density, and ion energy controls. Plasma processing tools can, in some cases, be required to sustain a stable plasma in a variety of process gases and under a variety of different conditions (e.g. gas flow, gas pressure, etc.).

### SUMMARY

Aspects and advantages of the invention will be set forth in part in the following description, or may be obvious from the description, or may be learned through practice of the invention.

One example aspect of the present disclosure is directed to a plasma processing apparatus. The plasma processing apparatus can include a plasma chamber, a dielectric wall forming at least a portion of the plasma chamber, an inductive coupling element located proximate the dielectric wall. The inductive coupling element can generate a plasma in the plasma chamber when energized with radio frequency (RF) energy. The plasma processing apparatus can further include an electrostatic shield located between the inductive coupling element and the dielectric wall. The electrostatic shield can include a plurality of shield plates. A surface of each shield plate can be proximate the dielectric wall has at least one edge close to the dielectric wall rounded with a radius of greater than or equal to about 1 millimeter.

Another example aspect of the present disclosure is directed to a plasma processing apparatus. The plasma processing apparatus can include a plasma chamber, a dielectric wall forming at least a portion of the plasma chamber, an inductive coupling element located proximate the dielectric wall. The inductive coupling element can generate a plasma in the plasma chamber when energized with radio frequency (RF) energy. The plasma processing apparatus can further include an electrostatic shield located between the inductive coupling element and the dielectric wall. The electrostatic shield can include a plurality of slots. Each slot of the plurality of slots is angled relative to a direction perpendicular to the dielectric wall to produce an oblique line of sight angle from the inductive coupling element to the dielectric wall.

Yet Another example aspect of the present disclosure is directed to a plasma processing apparatus. The plasma processing apparatus can include a plasma chamber, a dielectric wall forming at least a portion of the plasma chamber, an inductive coupling element located proximate the dielectric wall. The inductive coupling element can generate a plasma in the plasma chamber when energized with radio frequency (RF) energy. The plasma processing apparatus can further include an electrostatic shield located between the inductive coupling element and the dielectric wall. The electrostatic shield can include a plurality of shield plates. Each of the plurality of shield plates can include a first part and a second part, and the first part is in proximity to the dielectric wall and the second part is further away from the dielectric wall. For any two neighboring shield plates of the plurality of shield plates, a first part of one shield plate overlaps a second part of other shield plate without contacting the second part to obstruct a line of sight from part of the inductive coupling element to the dielectric wall.

Yet Another example aspect of the present disclosure is directed to a plasma processing apparatus. The plasma processing apparatus can include a plasma chamber, a dielectric wall forming at least a portion of the plasma chamber, an inductive coupling element located proximate the dielectric wall. The inductive coupling element can generate a plasma in the plasma chamber when energized with radio frequency (RF) energy. The plasma processing apparatus can further include an electrostatic shield located between the inductive coupling element and the dielectric wall. The electrostatic shield can include a first layer and a second layer. The first layer can include a first plurality of shield plates and the second layer can include a second plurality of shield plates. The first and second plurality of shield plates are arranged such that each gap between two neighboring shield plates of the first plurality of shield plates overlaps a shield plate of the second plurality of shield plates to obstruct a line of sight from the inductive coupling element to the dielectric wall. One of the first layer and the second layer is connected to electrical ground through a low impedance and the other of the first layer and the second layer is connected to ground through a variable reactive impedance. The variable reactive impedance can be adjustable by an automated control system such that the second plurality of shield plates have a voltage that is variable between a first voltage to ignite the plasma and a second voltage to sustain the plasma.

Variations and modifications can be made to example embodiments of the present disclosure.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure to one of ordinary skill in the art is set forth more particularly in the remainder of the specification, including reference to the accompanying figures, in which:

FIG. 1 depicts an example plasma processing apparatus according to example embodiments of the present disclosure;

FIG. 2 depicts a cross-section of an example electrostatic shield that can be used in conjunction with a plasma processing apparatus according to example embodiments of the present disclosure;

FIG. 3 depicts a cross-section of an example electrostatic shield that can be used in conjunction with a plasma processing apparatus according to example embodiments of the present disclosure;

FIG. 4 depicts a cross-section of an example electrostatic shield that can be used in conjunction with a plasma processing apparatus according to example embodiments of the present disclosure;

FIG. 5 depicts a cross-section of an example electrostatic shield that can be used in conjunction with a plasma processing apparatus according to example embodiments of the present disclosure;

FIG. 6 depicts a cross-section of an example electrostatic shield that can be used in conjunction with a plasma processing apparatus according to example embodiments of the present disclosure;

FIG. 7 depicts a cross-section of an example electrostatic shield that can be used in conjunction with a plasma processing apparatus according to example embodiments of the present disclosure;

FIG. 8 depicts a cross-section of an example electrostatic shield that can be used in conjunction with a plasma processing apparatus according to example embodiments of the present disclosure;

FIG. 9 depicts a cross-section of an example grounded electrostatic shield that can be used in conjunction with a plasma processing apparatus according to example embodiments of the present disclosure;

FIG. 10 depicts a cross-section of an example grounded electrostatic shield that can be used in conjunction with a plasma processing apparatus according to example embodiments of the present disclosure.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Example aspects of the present disclosure are directed to improved designs of electrostatic shields to be used in conjunction with inductive plasma sources to reduce capacitive coupling between plasma source components and plasma. For instance, a plasma processing apparatus can include one or more inductive coupling elements (e.g., antennas, helical coils, or coils with spiral or other shapes) and an electrostatic shield to reduce capacitive coupling from the inductive coupling elements to sustain an inductive plasma within a processing chamber for processing a workpiece (e.g., performing a dry etch process and/or a dry strip process). The inductive coupling element(s) can be arranged proximate a dielectric wall forming a part of a plasma chamber. The inductive coupling element(s) can be energized with RF energy by providing RF electric current through the inductive coupling element(s) to induce a substantially inductive plasma in a process gas in the plasma chamber.

Electrostatic shields have been used for inductively coupled plasma sources to address some significant challenges. For instance, because there is usually a high voltage on one or more turns of an inductive coils for an inductive plasma, there can be capacitive coupling between the coil and the dielectric vessel. The capacitive coupling can increase the energy of ion bombardment in particular areas of the inner, plasma-facing the plasma dielectric vessel. This ion bombardment can increase etching or sputtering of the dielectric vessel causing contamination. This can also over time cause roughening of the inner surface of the dielectric wall adjacent the coil or interior walls of other parts of the plasma chamber to change the process performance of the chamber. It can also cause particulate release from the walls into the process gas and onto the workpiece. As another example, the capacitive coupling can cause RF currents to pass from induction coil into the plasma resulting in modulation of the plasma potential. This modulation can affect the sheath potentials at grounded walls or at the workpiece and thereby energies of ions bombarding both the workpiece and the walls of the plasma chamber. Thus, changing the inductive power which is supposed to affect ion current density, but not ion energy, due to capacitive coupling usually does in fact affect ion energy on the workpiece.

Some example approaches to reducing capacitive coupling by using low frequency inductive RF excitation generally are not often used for semiconductor processing because they have less flexibility in RF power application due to the difficulty of automating high-precision impedance matching for frequencies of less than about 1 MHz. At lower excitation frequencies, RF currents are much larger than RF currents at frequencies above 10 MHz, causing more heating of components in the matching network, and therefore, the net power delivered to the plasma is more uncertain.

Other example types of processing plasma chambers use more distant positioning of the antenna/coil to reduce capacitive coupling, but these designs generally dissipate much more power in the walls of the RF power containment enclosure due to the reduced strength of coupling of the antenna/coil to the plasma. This makes the power losses in the enclosure of the source, the matching network and antenna a more significant fraction of the applied power and the power actually delivered to the plasma load can be uncertain by more than tens of Watts.

Electrostatic shields are typically made of conducting material, positioned between the inductive coupling element(s) and the dielectric wall to reduce capacitive coupling between the inductive coupling element(s) and the plasma sustained in an evacuated chamber. In some example applications, electrostatic shields typically include a plurality of metal or other conducting material plates with gaps roughly parallel to an axis of the chamber, or a metal enclosure with openings/slots that are roughly parallel to the chamber axis (typically, the chamber has axis-symmetry). The plates or metal enclosure surround a dielectric chamber wall that can be cylindrical or domed, where gaps between adjacent shield plates (or slots in the metal enclosure) can have lengths approximately perpendicular to the direction of the current flow in the antenna or the inductive coupling element. The electrostatic shield can in some examples be positioned proximate to the dielectric wall, covering at least a majority of that wall area, and in some example embodiments covering a majority of the area that lies between the antenna and the plasma.

According to example aspects of the present disclosure, an electrostatic shield can have one or more layers of shield plates made of conducting material to intercept most (e.g., from about 50% to greater than about 90%) of the RF displacement currents from the induction coil so that the capacitive coupling of RF current from the coil to the plasma is commensurately reduced. The resulting plasma typically can have up to about an order of magnitude reduction of the RF modulation of the plasma potential as compared with an unshielded source having the same configuration, as well as a substantial reduction in ion bombardment of the dielectric wall. As a result, use of an electrostatic shield can typically lead to substantially improved and more independent control over the plasma potential and energy of ion bombardment of wafer/substrate as well as dielectric and conducting walls of the chamber as compared with unshielded inductive sources.

In some example applications, the capacitive coupling from coil to plasma in cylindrical chambers is substantially reduced by multiple metal plates interposed between the coil and dielectric wall with gaps between them, or cylindrical shield with machined slots. However, to meet the increasingly stringent requirements of sub-10 nm devices, the capacitive coupling may need to be reduced further.

In some example applications, a chamber can have a dielectric wall with a domed shape and be covered by a shield that can be shaped like a conic section or dome. In such cases a long direction of slots or gaps between plates typically can lie in a plane that contains a symmetry axis of the cone or dome, as seen in some example applications. A plate of any of such electrostatic shield can have a voltage that varies across the surface of the plate from an edge adjacent one slot or gap, to the opposing edge bordering the nearest adjacent slot or gap. The voltage is inductively coupled by rapidly changing magnetic field produced by the antenna or induction coil when RF power is provided to the antenna or induction coil. Further, the plate of an electrostatic shield can also receive substantial RF displacement currents, directly from the antenna or induction coil by capacitive coupling. Either or both of these mechanisms of coupling can cause an RF potential distribution on the plate in which an electric field is the strongest near the boundaries/edges of a plate bordering a gap or slot. Such electrical fields can be stronger, the closer the plate or shield is to the dielectric wall. The electrical field coming from these parts of a plate can be large and cause high RF currents to conduct capacitively to the plasma through the dielectric wall nearest the edges of a metal plate at the boundaries of the slots. This electrical field and RF current from the edges of a plate combines with the electrical field produced directly by the potential on the antenna or induction coil which also conducts displacement current to the plasma mainly through the middle of the gap or slot between plates. In combination these mechanisms increase the plasma potential within and around the slots or gaps, and this increases the electrical field and thereby the ion energies bombarding the dielectric walls. This increase in ion energies results in increased etching and sputtering of the dielectric wall material, leading to contamination of the plasma, roughening of the inner surface of the adjacent dielectric wall and loss of device yield.

In some example, electrostatic shields, the slots or gaps of the shield plates of an electrostatic shield can be machined from a metal cylinder, conic section, dome or other shape and hence the edges of slots or gaps can be “square”. Further, these edges can be very close to the dielectric wall of the chamber, and therefore the RF electric field strength at the surface of the dielectric wall can be very high, inducing a high RF bias voltage on the inner surface of the wall. The electrical field from one plate across the gap or slot to the adjacent plate increases as the slot size decreases due to the decreasing distance between the edges of the adjacent plates on either side of said slot. These electrical fields on the edges of the slots or gaps capacitively couple through the dielectric wall to the plasma, increasing the energies of ions bombarding that wall. Further, the RF electric field originating from the coil potential that penetrates directly through the gap or slot between plates increases substantially as the size of the gap between plates or slot width increase.

In one example aspect of the present disclosure, rounding the edges of a plate or edges bordering a slot, specifically for edges closest to the dielectric wall, with simple or compound radius between about 1 mm and about 25 mm (e.g., removing any seams or sharp edges as part of any radius or transition to radius) can reduce the electrical fields that cause etching or sputtering of the inner wall of the dielectric because such configuration can substantially reduce high-electric-field in areas near the edge of the plate or near a gap between plates.

In some embodiments, one or more shield plates can have long edges or boundaries and/or corners that are rounded with a radius greater than about 1 mm to reduce electric fields at a surface of any suitable dielectric wall proximate the shield plates. Such edge of a plate can be made rounded about an axis parallel to the surfaces of the plate and/or dielectric wall so that there is a radius of curvature of the boundary or edge of the plate, adjacent and approximately parallel to the gap or slot. The radius of curvature can be between about 1 mm and about 25 mm, so that the electrical field at that boundary of the plate where it is closest to the dielectric wall can be reduced. In some embodiments, one or more shield plates can have an RF electric potential adjusted via a tunable impedance that can reduce RF voltage on the shield plate and can commensurately reduce an electric field near edges of the shield plate during plasma operation.

In some embodiments, the electric field coming from the shield plate can be produced in part by the voltage induced between one edge of the shield plate and the opposite edge of that plate by the changing magnetic flux from the inductive coupling element (e.g., antenna or induction coil). Since such plate does subtend a fraction of a turn that is effectively in parallel with some length of the inductive coupling element (e.g., antenna or induction coil), a voltage can be induced between leading and trailing edges of the plate (whose long direction(s) make an angle greater than about 30° to the direction of current flow in the inductive coupling element or antenna). In some embodiments where the coil is helical with axis of the helix coaxial with the axis of a cylindrical chamber, the long direction of the boundary of a plate along a gap or slot can be approximately parallel to the cylinder axis which is the dominant direction of the magnetic field produced by the inductive coupling element (e.g., antenna or induction coil). A voltage is thereby induced between the two opposite long edges of this plate by the changing magnetic field produced by the inductive coupling element (e.g., antenna or induction coil).

In some embodiments, when the inductive coupling element is a coil of a spiral shape, that can be approximately in a plane or a curved or domed surface positioned adjacent an area of a plasma chamber, the plates or areas between slots can have an approximately triangular (plane triangle or spherical triangle) or trapezoidal shape. In this case the distance from one such edge of a plate to the opposite edge of that plate decreases the closer one is to the approximate center of the spiral. When RF power is provided by driving an RF current in the inductive coupling element (e.g., antenna or induction coil), the RF power induces a voltage difference between these two opposite edges as in the case of a helical coil about a cylinder. In some embodiments with a spiral coil of approximately planar (flat or slightly domed) gross shape, the axis through the center and perpendicular to the spiral, can also be approximately perpendicular to the dielectric wall nearest the shield and the axis can also be an approximate point of convergence of the gaps between plates of the shield. In this case, the axis about which the radius of curvature of an edge can be machined or otherwise defined parallel or at an angel less than 10° to the long direction of the slot or gap and to an edge of a plate or slot nearer the surface of the dielectric.

In some instances, slots for electrostatic shields can have about 15 mm to about 20 mm wide to provide sufficient capacitive coupling to reliably and rapidly ignite the plasma, even at gas pressures of the order or greater than 100 Pascals. However, once the plasma has been ignited and is being sustained by the inductive coupled RF power, such large openings and the substantial capacitive coupling they bring may no longer be needed for sustaining the plasma. However, such gaps or slots can continue to allow penetration of the electrostatic field from the antenna or induction coil, thereby causing enhanced ion bombardment of the dielectric and etching of the dielectric walls of the plasma chamber.

In some embodiments, the slots can be narrowed and in some embodiments there can be more plates and more slots associated with any suitable inductive coupling element (e.g., antenna or induction coil) so that the capacitive coupling through the gaps or slots can be reduced, while still permitting rapid and reliable ignition of the plasma. Such narrower gaps then permit reduced capacitive coupling and consequent surface bombardment of the dielectric wall.

According to example aspects of the present disclosure, an electrostatic shield causing such reduced capacitive coupling can be located between an inductive coupling element and a dielectric wall forming at least a portion of the plasma chamber. The electrostatic shield can have openings or gaps that can permit RF magnetic fields to penetrate from the inductive coupling element to the dielectric wall. In some embodiments, the plates individually or an electrostatic shield shell or enclosure can be connected to an electrical ground, directly or through some variable, reactive impedance. In some embodiments where the electrostatic shield has multiple shield plates, the plates can be connected to each other each to the adjacent plates or to a central grounding strap or element.

RF current that penetrates through gaps between adjacent shield plates or slots and through the dielectric wall to the plasma can depend inversely on a depth of a gap from the electrostatic shield to the dielectric wall. In some embodiments, to better reduce capacitive coupling from the inductive coupling element (e.g., antenna or induction coil) to plasma, gaps between adjacent shield plates or width of each slot can be reduced. In some embodiments, edges of the shield plates or edges of slots can be rounded (e.g., with a radius equivalent to a substantial fraction, at least about ¼^{th} of a thickness of a shield plate) about an axis that is parallel to the edge of the slot or to the gap between plates. In some embodiments, a curvature radius of a rounded edge can be in a range of about 1 mm to about 15 mm, such as in a range of about 2 mm to about 10 mm. In this manner, an electric field at the surface of the dielectric wall can be reduced relative to unrounded edges of the shield plates or edges of slots.

In some embodiments, example embodiments of the present disclosure can provide a gap between adjacent shield plates or width of each slot in the electrostatic shield in a range of about 2 mm to about 30 mm, such as in a range of about 3 mm to 20 mm. In some embodiments, a gap from the shield plates to the outer surface of the dielectric wall can be in a range of about 0.1 mm to about 30 mm (e.g., in a range of about 1 mm to 20 mm).

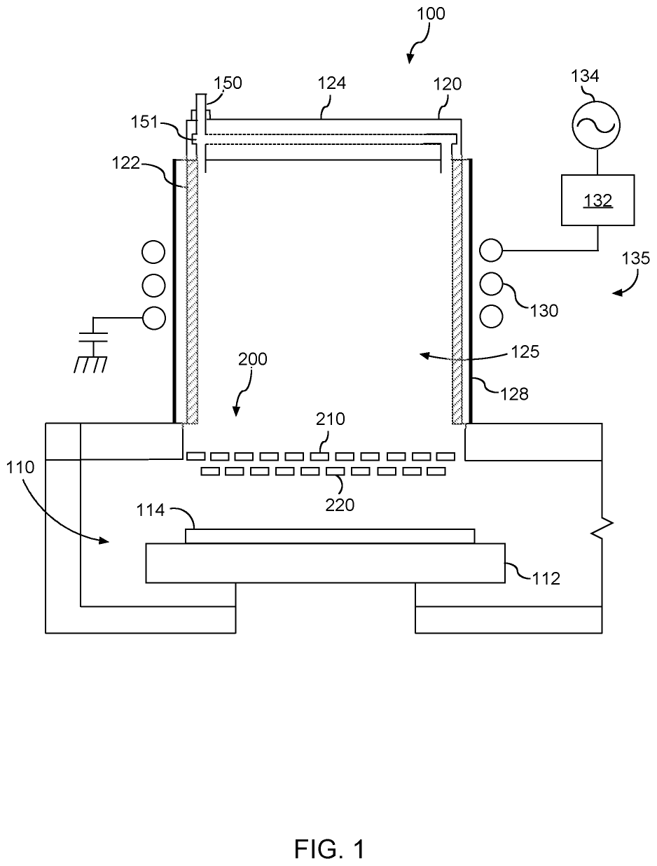

In some embodiments, the electrostatic shield can include portions (e.g., shield plates) with increased thickness. The thickness of each of the shield plates of the electrostatic shield can be quantified relative to size of the gaps between adjacent shield plates or width of each slot. For instance, a thickness of each of the shield plates of the electrostatic shield can be in a range of about 1 mm to about 20 mm (e.g., in a range of about 2 mm to 15 mm). In some embodiments, instead of using a substantial thickness (>5 mm) of the material of a shield, a shield or plates may be made of thinner metal (<4 mm) but may be formed to be concave (as seen from outside the plasma chamber) and have substantial curvature at their edges adjacent the dielectric wall that border the gaps between plates. The surface of a shield plate facing the plasma chamber would thus have rounding at its edges as in a thicker metal shield plate as seen in FIG. 1. This design has a further benefit in reducing the capacitive coupling between the induction element and the shield.

In some embodiments, the electrostatic shield can have multiple layers. For instance, the electrostatic shield can have an inner layer that is closer to the dielectric wall and an outer layer that is further away from the dielectric wall. The outer layer, if the outer layer can cover the open spaces between the plates of the inner layer, can further reduce capacitive coupling from the inductive coupling element to plasma. If that layer of shield plates is electrically grounded or has a very low impedance to ground, capacitive coupling can be further reduced, and it can also result in reduced ion bombardment of the dielectric wall. The inner and outer layers can be arranged such that each gap between two neighboring shield plates of the inner layer can partially overlap a shield plate of the outer layer to obstruct (e.g., partially block, nearly or completely block) a line of sight radially from the inductive coupling element to the dielectric wall, thereby reducing the total line of sight from the inductive coupling element to the dielectric wall.

In some embodiments, the inner and outer layers of a plate can include a single piece of material that can extend from a part nearer the surface of the dielectric wall to a part farther from the dielectric wall, overlapping without touching an adjacent plate, thereby reducing the line of sight from the inductive coupling element (e.g., antenna or induction coil) to the dielectric wall. Alternatively, the inner layer or the outer layer can have a separate structure that can be independently connected to a variable, partially reactive, electrical ground which at a setting effectively ground the shield plate or allow it to high impedance to effectively float electrically.

In some embodiments, each layer can have multiple shield plates, each of the shield plates can have an elliptical cross-section or otherwise rounded cross-section. For instance, the electrostatic shield can have multiple overlapping rods where each has elliptical/flattened round shaped cross-section such that they collectively block line of sight from the inductive coupling element to the dielectric wall.

According to example aspects of the present disclosure, an electrostatic shield can also have multiple slots in a metal or electrically conducting cover for some portion of the dielectric wall. In some embodiments where the inductive coupling element is a roughly helical coil, an electrostatic shield can be a slotted cylinder with a thickness of metal or conducting material and sufficiently small fraction of open area between antenna and dielectric wall to substantially reduce capacitive coupling by a factor greater than about 30 times (˜1.5 orders of magnitude). Each slot can be angled relative to a radial cut direction (e.g., relative to a direction perpendicular to the dielectric wall) to produce a deeper and oblique line of sight angle from the inductive coupling element to the dielectric wall of the plasma chamber. In some embodiments, each slot can be angled at about 45°+/−15° relative to the direction perpendicular to the dielectric wall. The width of these slots can be between about 1 mm and 20 mm (e.g., between about 2 mm and 10 mm). The thickness of the shield in this case can be greater than in some other embodiments—between about 10 mm and 30 mm. This thicker shield with angled slots reduces the capacitive coupling more than simple apertures in a metal cylinder whose wall thickness is less than about 25% of the width of the slots. In some embodiments, the wall thickness with angled slots is more than about 25% of the width of a slot so that capacitive coupling is reduced more than that in conventional shield technology. In some embodiments, the thickness of the shield material can be more than about 50% of the width of an angled slot.

In some embodiments, each slot of the electrostatic shield can be angled in the same direction to create a clockwise or counter-clockwise pattern between the electrostatic shield and the dielectric wall. The angled slots can help air flow between the electrostatic shield and the dielectric wall to improve the cooling such that the dielectric wall damage from plasma at high temperature can be reduced. Gas injection into space between the electrostatic shield can be clockwise or counterclockwise such that different directions of air flow can be created. Rounding of the edges adjacent the dielectric can help to promote cooling gas flow adjacent the dielectric wall that receives heat from the plasma within by facilitating the convergence of the gas stream into the gap between shield and dielectric wall. Further, the rounding of the edge adjacent the dielectric wall of the angled slot reduces the electrical field at the surface of the dielectric wall, thereby reducing the ion bombardment and erosion of the dielectric wall.

In some embodiments, shield plates can be of two or more types such that different types of shield plates can be placed alternately around the dielectric wall. For instance, the shield plates can alternate between a first type having edges (e.g., rounded edges) closer to the outer surface of the dielectric wall and a second type having edges further from the outer surface of the dielectric wall. Such feature can greatly reduce the capacitive coupling from the inductive coupling element directly through the gap between adjacent shield plates such that very little rf current can be conducted from the inductive coupling element to the plasma. In some embodiments, some or all shield plates proximate to the dielectric wall can be shaped such that the edges can have a larger radius of curvature—between about 1 mm and 25 mm, thereby reducing the electrical field at the edges that is caused by magnetic induction of a voltage on the plates from the inductive coupling element, and thereby reducing the capacitive coupling of current from the edges of the plates through the dielectric wall.

According to example aspects of the present disclosure, an electrostatic shield can include multiple shield plates. Each shield plate can have a first part and a second part. The first part can be in proximity to the dielectric wall and the second part can be further away from the dielectric wall. For any two neighboring shield plates, a first part of one shield plate can overlap a second part of other shield plate without contacting the second part to obstruct (e.g., more fully obstruct) a line of sight from the inductive coupling element to the dielectric wall. In some embodiments, each such shield plate can have one or more of edges adjacent the dielectric wall that are rounded about an axis parallel with that edge and to surface of the dielectric wall. In some embodiments, the shield plates can be arranged in a clockwise or counter clockwise outward direction.

Electrostatic shields according to example aspects of the present disclosure can provide a number of technical effects and benefits. For instance, electrostatic shields configured according to example embodiments of the present disclosure can substantially reduce capacitively coupled electric fields on the surface of the dielectric wall of a plasma chamber. The reduced electrical field can be maintained during a percentage of plasma operating time to reduce the energy of ion bombardment on the dielectric wall. Such percentage can be very large, being up to about 99.9% when the reduced field is begun as soon as the plasma is ignited and continues until RF power has been stopped. In addition, particle formation in the plasma chamber can be reduced when generating plasmas from reducing gases, such as hydrogen.

Aspects of the present disclosure are discussed with reference to a “workpiece”, “substrate”, or “wafer” for purposes of illustration and discussion. Those of ordinary skill in the art, using the disclosures provided herein, will understand that the example aspects of the present disclosure can be used in association with any semiconductor substrate or other suitable substrate or workpiece. A “pedestal” is any structure that can be used to support a workpiece. In addition, the use of the term “about” in conjunction with a numerical value is intended to refer to within 10% of the stated numerical value.

FIG. 1 depicts an example plasma processing apparatus according to example embodiments of the present disclosure. As illustrated, the plasma processing apparatus 100 includes a processing chamber 110 and a plasma chamber 120 that is separated from the processing chamber 110. The processing chamber 110 includes a workpiece support or pedestal 112 operable to hold a workpiece 114 to be processed, such as a semiconductor wafer. In this example illustration, a plasma is generated in the plasma chamber 120 (i.e., plasma generation region) by a predominantly inductively coupled plasma source 135 and desired species are channeled from the plasma chamber 120 to the surface of substrate 114 through a separation grid assembly 200.

The plasma chamber 120 includes a dielectric side wall 122 (also referred to as a dielectric wall) and a ceiling 124. The dielectric side wall 122, ceiling 124, and separation grid 200 define a plasma chamber interior 125. The dielectric side wall 122 can be formed from a dielectric material, such as quartz and/or alumina. The inductively coupled plasma source 135 can include an inductive coupling element (e.g., antenna or induction coil) 130 disposed proximate or around the dielectric side wall 122 about the plasma chamber 120. The induction coil 130 is coupled to an RF power generator 134 through a suitable impedance matching network 132. Process gases (e.g., a hydrogen containing gas, or oxygen-containing gas, and optionally a relatively inert gas that can be called a “carrier” gas) can be provided to the chamber interior from a gas supply 150, either via an annular gas distribution channel 151, or showerhead or other suitable gas introduction mechanism. When the induction coil 130 is energized with RF power from the RF power generator 134, a plasma can be generated in the plasma chamber 120. In a particular embodiment, the plasma processing apparatus 100 can include a grounded electrostatic shield 128 that can be interposed between the induction coil/antenna 130 and the dielectric wall, in proximity to the dielectric wall.

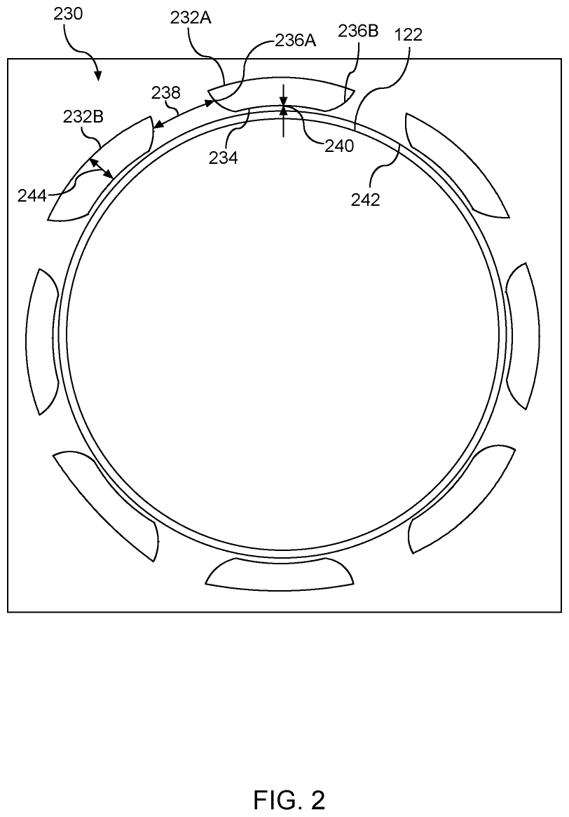

The electrostatic shield 128 reduces capacitive coupling from the induction coil 130 to the plasma. In some embodiments, the electrostatic shield 128 for a cylindrical source can have one or more layers of shield plates made of conducting material with the gaps between adjacent shield plates parallel to the cylinder symmetry axis. Each shield plate can have a shaped cross-section (as sectioned by a plane perpendicular to the cylinder axis) (as shown in FIG. 2) to reduce electric fields at an outer surface of the dielectric side wall 122. Each shield plate can have an RF potential set, effectively grounded or at some desired value via a tunable impedance that can in some embodiments of the process provide a higher RF potential during plasma ignition and then reduce RF voltage on that layer of the shield plate during plasma sustaining.

In some embodiments, the electrostatic shield 128 can include multiple shield plates and these plates can be positioned as a single ring or double ring with a second ring outside the first ring. A surface of each shield plate proximate the dielectric side wall 122 can have one or more rounded edges, as further described below in FIG. 2. In some embodiments, a gap located between two neighboring shield plates of the electrostatic shield 128 can be in a range of about 1 millimeter to 30 millimeters (e.g., in a range between about 2 millimeters and 20 millimeters). A gap between the electrostatic shield 128 and an outer surface of the dielectric side wall 122 can be in a range of about 0.5 millimeters to about 15 millimeters. A thickness of each shield plate can be in a range of about 1 millimeters to about 15 millimeters (e.g., between about 2 millimeters and 10 millimeters). A curvature radius of a rounded edge can be in a range of about 1 millimeter to about 15 millimeters.

In some embodiments, the electrostatic shield 128 can have multiple approximately conforming layers that can be spaced, each from that inside and outside by between 2 mm and about 20 mm. For instance, the electrostatic shield 128 can have an inner layer that roughly conforms to and is proximate the dielectric side wall 122 and an outer layer that can be circular or generally a convex shape is further away from the dielectric side wall 122 in a distance range of about 2 mm to about 20 mm. The outer layer by being positioned to partially or completely block the openings of the inner layer. If the outer layer is grounded or its impedance to ground is very low, the outer layer can further and substantially reduce capacitive coupling from the induction coil 130 to the plasma, thereby resulting in reduced energy of ion bombardment of the dielectric side wall 122. The inner and outer layers can be arranged such that ensemble shapes of the inner and outer layers are conformal. Further, the plates or shields can be so configured that each gap between two neighboring shield plates of the inner layer can overlap, in part or completely a shield plate of the outer layer to obstruct (e.g., partially block, nearly or completely block) a line of sight radially from the induction coil 130 to the dielectric side wall 122, thereby greatly reducing the total line of sight from the induction coil 130 to the dielectric side wall 122. In some embodiments, a plate of the inner layer can be of a single piece of material with a plate or plates in the outer layer. In some embodiments, the plates of the inner layer or the plates of the outer layer can have a separate structure that can be independently adjusted to a very low RF voltage by reducing a substantially reactive impedance, or to effectively float by increasing that impedance by means of an automated control system that can vary that reactive impedance.

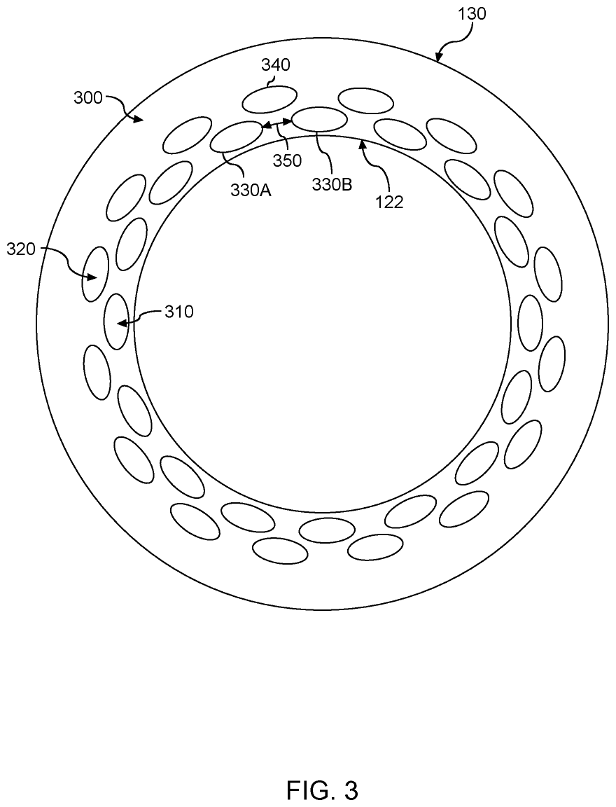

In some embodiments, each layer of the electrostatic shield 128 can have multiple rounded shield plates, such that each of the shield plate can have an approximately elliptical or oval cross-section or round or approximately rounded cross-section. For instance, the electrostatic shield 128 can have multiple overlapping rods that can have elliptical/flattened round shaped cross-section for each rod to largely block line of sight from the induction coil 130 to the dielectric side wall 122. Examples are further described below in FIG. 3 and FIGS. 8-10.

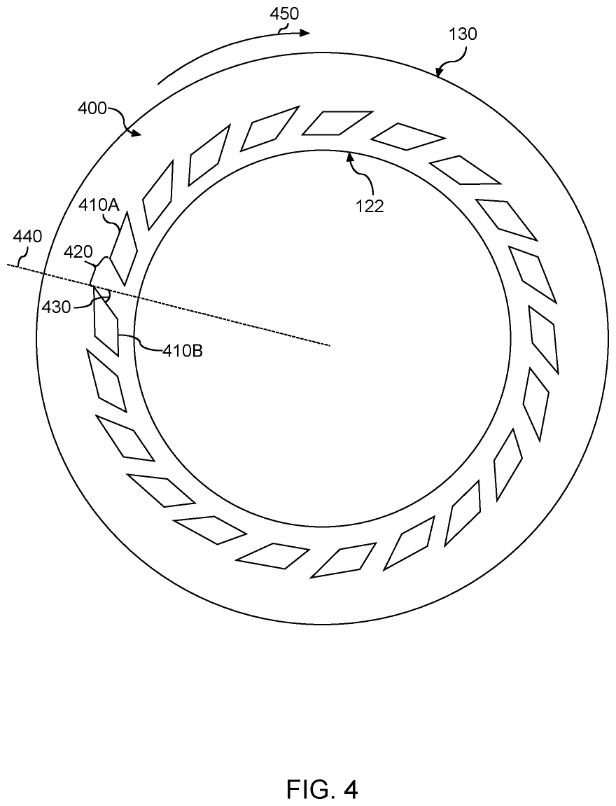

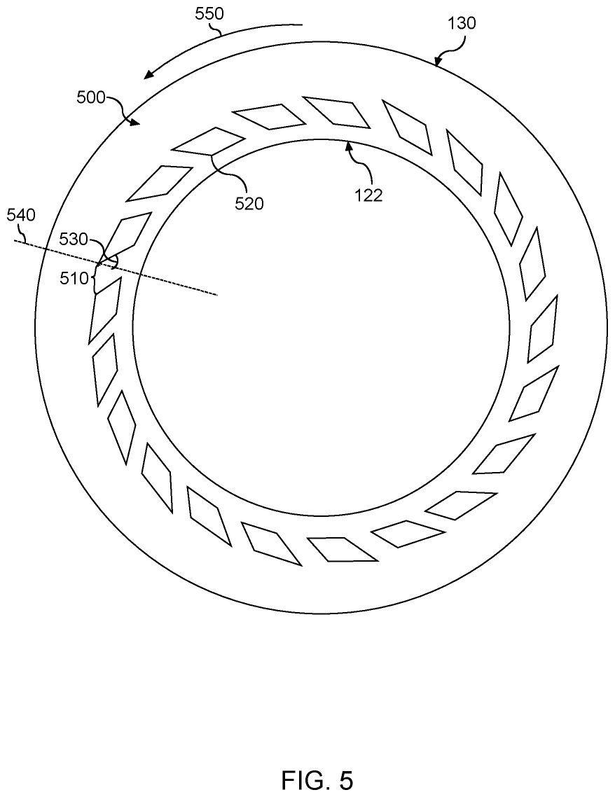

In some embodiments, the electrostatic shield 128 can have multiple slots. Each slot can be angled relative to a radial cut direction (e.g., relative to a direction perpendicular to the dielectric wall) to produce an oblique line of sight angle from the induction coil 130 to the dielectric side wall 122 of the plasma chamber 120. In some embodiments, each slot can be angled at about 45°+/−15° relative to the direction perpendicular to the dielectric side wall 122. In some embodiments, each slot of the electrostatic shield 128 can be angled in a clockwise direction to create a clockwise or counter-clockwise pattern between the electrostatic shield 128 and the dielectric side wall 122. The angled slots can help air flow between the electrostatic shield 128 and the dielectric side wall 122 to improve the cooling such that the Quartz damage from plasma at high temperature can be reduced. Gas injection into space between the electrostatic shield 128, for the purpose of cooling the dielectric wall, can be clockwise or counterclockwise such that different directions of air flow can be created. In some embodiments, the angled slots can have rounded edges adjacent the dielectric wall so that cooling air flow may more easily flow into the gap between shield and dielectric wall. Examples are further described below in FIG. 4 and FIG. 5.

In some embodiments, shield plates of the electrostatic shield 128 can have two or more types such that different types of shield plates can be placed alternately around the dielectric side wall 122. For instance, the shield plates can alternate between a first type having edges closer to the outer surface of the dielectric side wall 122 and a second type having edges further from the outer surface of the dielectric side wall 122. Such feature can greatly reduce the capacitive coupling from the inductive coupling element directly through the gap between adjacent shield plates such that almost no RF current can be conducted from the induction coil 130 to the plasma. In some embodiments, the shield plates of the electrostatic shield 128 can be shaped such that the edges closest to the dielectric wall can have a larger radius of curvature, thereby reducing the electrical field at the edges due to magnetic induction and thereby reducing the capacitive coupling of current through the dielectric side wall 122.

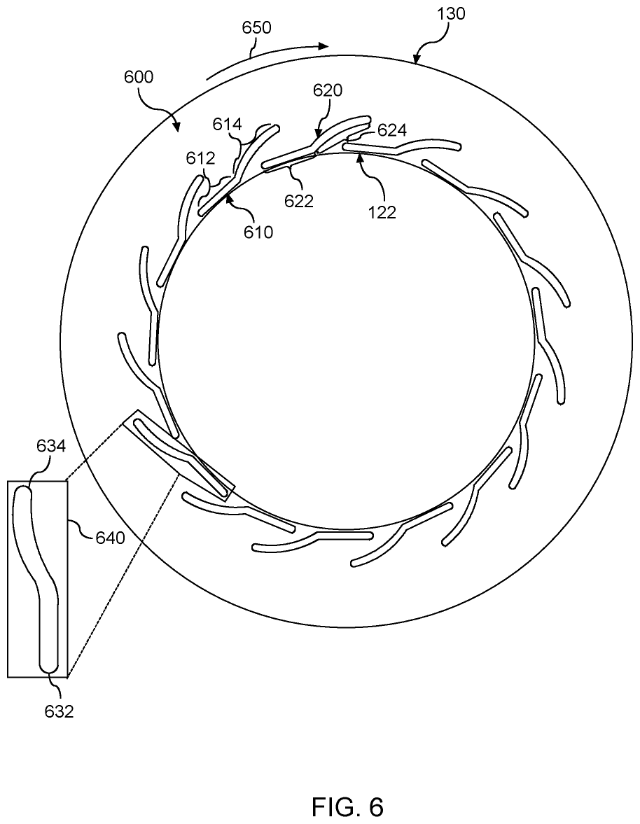

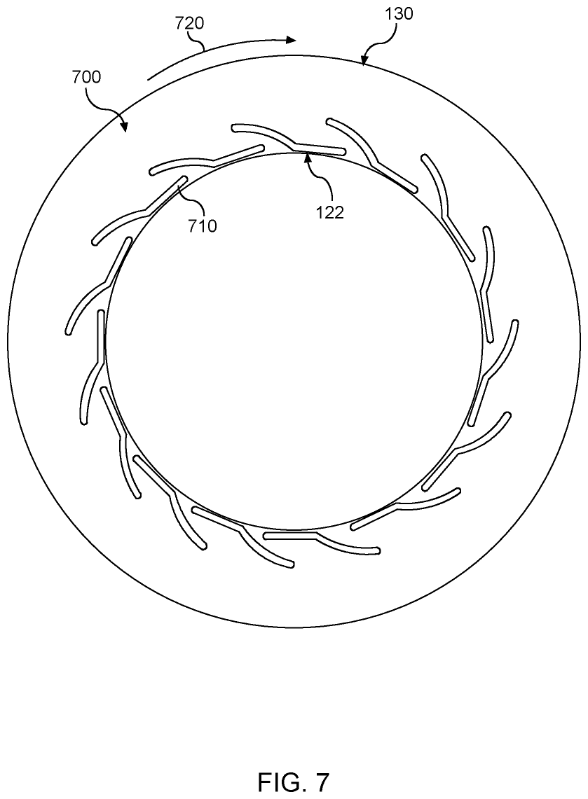

In some embodiments, the electrostatic shield 128 can include multiple shield plates. Each shield plate can have a first part and a second part. The first part can be in proximity to the dielectric side wall 122 and the second part can be further away from the dielectric side wall 122. For any two neighboring shield plates, a first part of one shield plate overlaps a second part of an adjacent shield plate without contacting the second part to obstruct a line of sight from the inductive coil 130 to the dielectric side wall 122. In some embodiments, each such shield plate can have rounded edges adjacent the dielectric wall. In some embodiments, the shield plates can be arranged in a clockwise or counter clockwise outward direction. Examples are further described below in FIG. 6 and FIG. 7.

Referring back to FIG. 1, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber 110.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern, or the patterns can be the same and the grids aligned relative to one another, or rotated, so that the holes in the first grid and the second grid do not overlap. In some embodiments, the grids are the same pattern but are misaligned so that the holes do not overlap and in consequence the charged particles will have to flow with the gas between the grids on the way from a hole in the first to a nearby hole in the second grid, thereby substantially recombining on the surfaces of the grids in their path through the offset holes of each grid plate 210, 220 in the separation grid. Neutral species (e.g., radicals), however, with their lower probability of recombination on the surface of a grid can flow relatively freely through the holes in the first grid plate 210 and the second grid plate 220 while not recombining. The size of the holes, alignment, pattern and thickness of each grid plate 210 and 220 can affect transparency for both charged and neutral particles.

FIG. 2 depicts a cross-section of an example electrostatic shield 230 that can be used in conjunction with the plasma processing apparatus 100 according to example embodiments of the present disclosure. As can been seen in FIG. 2, the electrostatic shield 230 includes eight shield plates (e.g., a shield plate 232A, a shield plate 232B and so forth). A surface 234 of the shield plate 232A proximate to the dielectric side wall 122 has two rounded edges 236A and 236B. A curvature radius of each rounded edge 236A or 236B can be in a range of about 1 millimeter to about 20 millimeters. A gap 240 between the surface 234 and an outer surface 242 of the dielectric side wall 122 can be in a range of about 0.5 millimeters to about 15 millimeters. A gap 238 located between the shield plate 232A and the shield plate 232B can be in a range of about 2 millimeters to 30 millimeters. A thickness 244 of the shield plate 232B can be in a range of about 1 millimeters to about 15 millimeters.

In some embodiments, the shield plates can be between about 5 millimeters and 10 millimeters thickness to improve the shielding of the dielectric wall and plasma from the inductive coupling element, while not being too bulky or heavy. In some embodiments, a shield plate can be thinner metal or other conductor (0.5 mm to 5 mm thickness) that is bent into a shape with curved (convex from the viewpoint of the dielectric wall) surfaces for the rounded edges closest to the dielectric wall, but having a surface with concave edges as seen from outside the shield. Such shield plates are lighter and superior in that such thinner shield plates have less capacitance to the inductive coupling element or antenna. Such plates can have a shape that conforms the inner, dielectric facing surface of a plate as shown in FIG. 2, including for one or more plates the surfaces 234, 236A and 236B, but not the outer surface of the plate 232A.

FIG. 3 depicts a cross-section of an example electrostatic shield 300 that can be used in conjunction with the plasma processing apparatus 100 according to example embodiments of the present disclosure. As can be seen in FIG. 3, the electrostatic shield 300 has an inner layer 310 and an outer layer 320. The inner layer 310 is proximate to the dielectric side wall 122 and the outer layer 320 is further away from the dielectric side wall 122. The inner layer 310 does not contact the outer layer 320. The inner layer 310 includes sixteen shield plates (e.g., shield plates 330A, 330B . . . ). The outer layer 320 includes sixteen shield plates (e.g., a shield plate 340 . . . ). Each shield plate of the inner layer 310 and the outer layer 320 has an elliptical or flattened-round shaped cross-section.

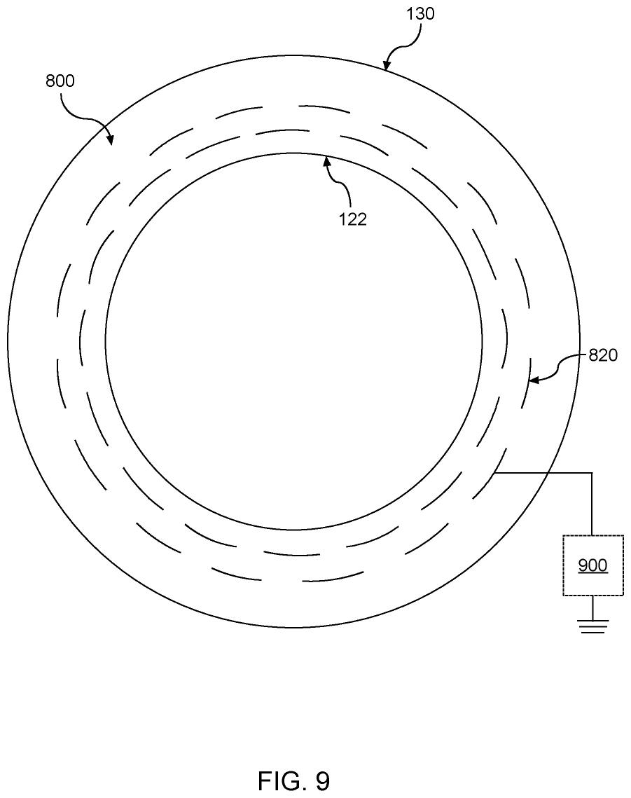

The inner layer 310 and outer layer 320 are arranged such that each gap between two neighboring shield plates of the inner layer 310 can overlap a shield plate of the outer layer 320 to obstruct (e.g., partially block, nearly or completely block) a line of sight radially from the induction coil 130 to the dielectric side wall 122, thereby greatly reducing the total line of sight from the induction coil 130 to the dielectric side wall 122. For example, a gap 350 between the shield plate 330A and the shield plate 330B overlaps the shield plate 340 of the outer layer 320. In some embodiments (not shown in FIG. 3), the inner layer 310 or the outer layer 320 can be grounded, directly or through one or more variable, reactive impedances. For example, the inner layer 310 or the outer layer 320 can be grounded via a circuit 900 shown in FIG. 9.

FIG. 4 depicts a cross-section of an example electrostatic shield 400 that can be used in conjunction with the plasma processing apparatus 100 according to example embodiments of the present disclosure. As can been seen in FIG. 4, the electrostatic shield 400 includes multiple slots (e.g., a slot 420) and multiple shield plates (e.g., a shield plate 410A and shield plate 410B). Each slot is located between two neighboring shield plates. For example, the slot 420 is located between the shield plates 410A and 410B. Each slot is angled at about 45°+/−15° relative to a direction perpendicular to the dielectric side wall 122. For example, an angle 430 between an edge of the slot 420 and a direction 440 perpendicular to the dielectric side wall 122 is about 45°+/−15°. Each slot of the electrostatic shield 400 is angled in a clockwise direction 450 to create a clockwise pattern between the electrostatic shield 400 and the dielectric side wall 122. The angled slots further reduce the line of sight from the inductive coupling element to the dielectric wall so that the capacitive coupling is significantly less (almost 50% less) than for straight slots of the same width, while the inductive coupling is only modestly reduced. Such angled plates may in some embodiments have edges proximate the dielectric wall that are rounded with radius of curvature between about 1 mm and 20 mm.

FIG. 5 depicts a cross-section of an example electrostatic shield 500 that can be used in conjunction with the plasma processing apparatus 100 according to example embodiments of the present disclosure. As can been seen in FIG. 5, the electrostatic shield 500 includes multiple slots (e.g., a slot 510) and multiple shield plates (e.g., a shield plate 520). Each slot is located between two neighboring shield plates. Each slot is angled at about 45°+/−15° relative to a direction perpendicular to the dielectric side wall 122. For example, an angle 530 between an edge of the slot 510 and a direction 540 perpendicular to the dielectric side wall 122 is about 45°+/−15°. Each slot of the electrostatic shield 500 is angled in a counter-clockwise direction 550 to create a counter-clockwise pattern between the electrostatic shield 500 and the dielectric side wall 122. This shield may have features as described for the shield with opposite slant as in FIG. 4 without deviating from the scope of the present disclosure.

FIG. 6 depicts a cross-section of an example electrostatic shield 600 that can be used in conjunction with the plasma processing apparatus 100 according to example embodiments of the present disclosure. As can be seen in FIG. 6, the electrostatic shield 600 includes multiple shield plates (e.g., a shield plate 610, a shield plate 620, and a shield plate 630). Each shield plate has a first part and a second part. For two neighboring shield plates, a first part of one shield plate overlaps a second part of other shield plate without contacting the second part to obstruct to varying degrees a line of sight from the inductive coil 130 to the dielectric side wall 122. In some embodiments the line of sight from the inductive coupling element to dielectric wall may be entirely blocked while in other configurations within the coverage of our disclosure there remains a small line of sight—less than about 30 degrees at most—to the dielectric wall from the inductive coupling element. For example, the shield plate 610 has a first part 612 and a second part 614. The shield plate 620 has a first part 622 and a second part 624. The first part 612 and the first part 622 are in proximity to the dielectric side wall 122. The second part 614 and the second part 622 are further away from the dielectric side wall 122. The first part 622 of the shield plate 620 overlaps the second part 614 of the shield plate 610 without contacting the second part 614. As can be seen in FIG. 6, each shield plate has rounded edges. For example, a zoom-in window 640 of the shield plate 630 shows the shield plate 630 having rounded edges 632 and 634. The shield plates are arranged in a clockwise outward direction 650.

FIG. 7 depicts a cross-section of an example electrostatic shield 700 that can be used in conjunction with the plasma processing apparatus 100 according to example embodiments of the present disclosure. As can been seen in FIG. 7, the electrostatic shield 700 includes multiple shield plates (e.g., a shield plate 710). Each shield plate has a first part and a second part. For two neighboring shield plates, a first part of one shield plate overlaps a second part of other shield plate without contacting the second part to obstruct a line of sight from the inductive coil 130 to the dielectric side wall 122. Each shield plate has rounded edges. The shield plates are arranged in a counter-clockwise outward direction 720. This shield may, as in those cases described above and shown in FIG. 6, have a range of maximal angles of visibility of the dielectric wall from the inductive coupling element substantially equal to the ranges described above for the clockwise case, referring to FIG. 6.

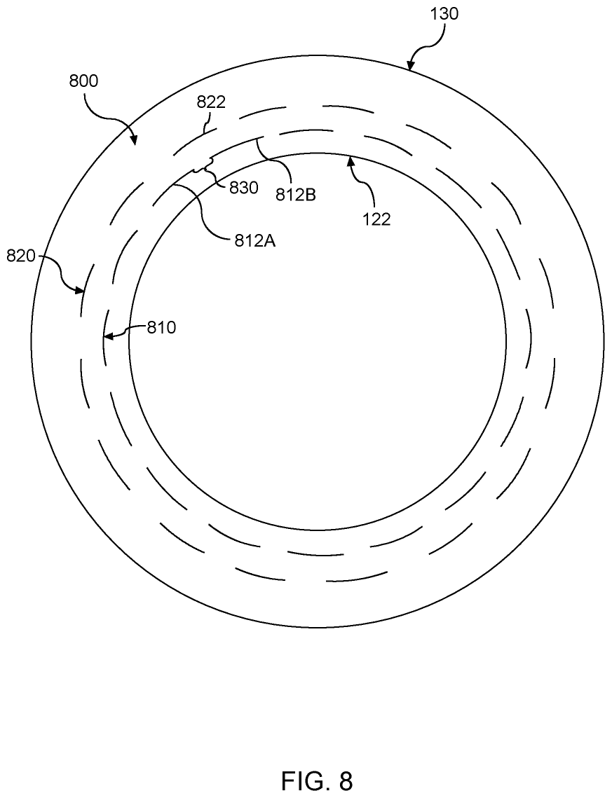

FIG. 8 depicts a cross-section of an example electrostatic shield 800 that can be used in conjunction with the plasma processing apparatus 100 according to example embodiments of the present disclosure. As can be seen in FIG. 8, the electrostatic shield 800 has an inner layer 810 and an outer layer 820. The inner layer 810 is proximate to the dielectric side wall 122 and the outer layer 820 is further away from the dielectric side wall 122. The inner layer as shown in 810 does not contact the outer layer 820 but has a gap of at least 2 mm. The inner layer 810 includes sixteen shield plates (e.g., shield plates 812A and 812B). The outer layer as in 320 includes sixteen shield plates (e.g., a shield plate 822). The inner layer 810 and outer layer 820 are arranged such that each gap between two neighboring shield plates of the inner layer 810 can overlap a shield plate of the outer layer 820 to obstruct (e.g., partially block, nearly or completely block) a line of sight radially from the induction coil 130 to the dielectric side wall 122, thereby greatly reducing the total line of sight from the induction coil 130 to the dielectric side wall 122. For example, a gap 830 between the shield plate 812A and the shield plate 812B overlaps the shield plate 822 of the outer layer 820. While two layers 810 and 820 are illustrated in FIG. 8, those of ordinary skill in the art using the disclosures provided herein, will understand that more than two layers (e.g., three layers, four layers, etc.) can be used without deviating from the scope of the present disclosure.

FIG. 9 depicts a cross-section of an example grounded electrostatic shield 800 that can be used in conjunction with the plasma processing apparatus 100 according to example embodiments of the present disclosure. As can be seen in FIG. 9, the outer layer 820 of the electrostatic shield 800 is connected to electrical ground via a circuit 900. The impedance of the inner shield to ground can be made to be very low by directly grounding that shield or by use of a fixed capacitance in series to electrical ground so that the inductance of the circuit for grounding the outer part of the shield is cancelled by the fixed capacitance, thereby reducing the RF voltage on the inner shield to a very small value. In some embodiments, the outer layer 820 can be grounded directly. The circuit 900 can include a variable impedance. As one example, the variable impedance can be provided by a series LC circuit with a variable capacitor to allow the impedance of the circuit 900 to be varied. The RF voltage on the shield part that is connected through the variable impedance is measured by a circuit (not shown in the figure), such as a capacitive divider, whose signal is provided to the automatic control system so that it can be monitored actively during the processing and so that the RF voltage on that part of the shield may be accurately controlled. This can allow the voltage on the outer layer 820, induced by the capacitive coupling from the inductive coupling element, to be controlled to take on two or more pre-determined values during various periods of the processing operation for a substrate or wafer. In some embodiments, the outer layer impedance to ground can be tuned to be high when it is desired to ignite the plasma, thereby causing the RF voltage on the outer shield to be greater than about 20 V_{RMS} and lowered to be less than about 20 V_{RMS} when the plasma has been ignited and is operating as required for processing. In some embodiments, the voltage on the outer shield is tuned by an automatic control system to be as small as possible—which can be less than 10 Volts RF amplitude and in some embodiments less than 5 Volts RF amplitude. In this case, when the outer shield voltage is high, there can be sufficient capacitive coupling to the dielectric wall to ignite the plasma, but after ignition the capacitive coupling is reduced to a smaller value that is adequate for sustaining the plasma.

The circuit 900 connecting the outer layer 820 to electrical ground can include a variable impedance that can be adjusted by an automated, computer-based control system to control the reactive impedance from near-zero Ohms to at least about 100 Ohms such that the RF current from the induction coil 130 to the outer layer 820 of the electrostatic shield 800 is able to flow to electrical ground causes the electrostatic shield 800 to have the requisite or desired RF voltage.

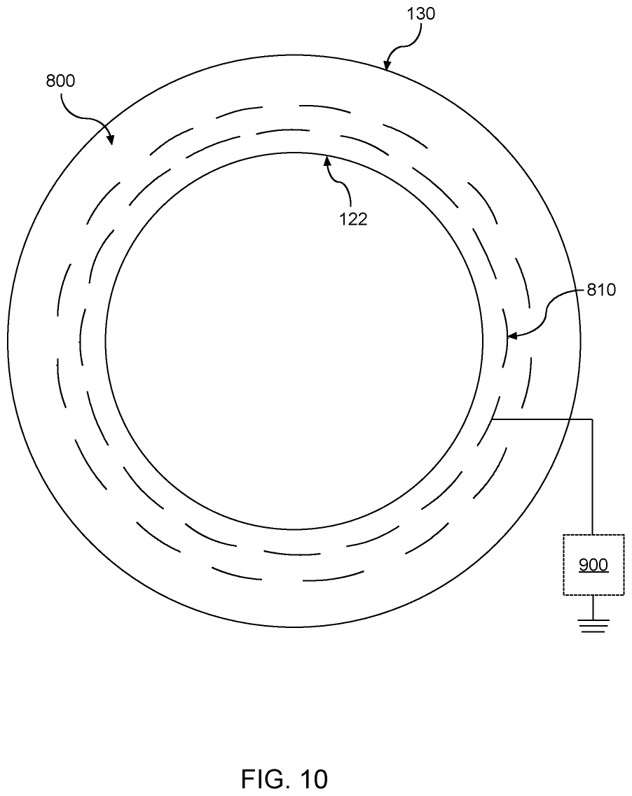

FIG. 10 depicts a cross-section of an example grounded electrostatic shield that can be used in conjunction with the plasma processing apparatus 100 according to example embodiments of the present disclosure. As can be seen in FIG. 10, the inner layer 810 of the electrostatic shield 800 is grounded via a circuit 900. The outer layer 820 can be grounded. The circuit 900 connecting the inner layer 810 to electrical ground can include a variable impedance that can vary from near-zero to at least about 100 Ohms such that the RF current from the antenna or induction coil 130 to the inner layer 810 of the electrostatic shield 800 causes the outer layer 820 to have a substantial RF voltage.

In some embodiments, the voltage on the inner layer 810, induced by the capacitive coupling from the inductive coupling element, can be monitored by a circuit that provides real-time measured values for the shield RF voltage so that using such values in conjunction with a mechanical controller using motor drives and gears (controlled by an automated computer control system) to adjust the reactive impedance so the shield voltage takes on two or more pre-determined values during various periods of the processing operation for a substrate or wafer. In some embodiments, the inner layer impedance to ground can be tuned to be high when it is desired to ignite the plasma, thereby causing the RF voltage on the outer layer 820 to be greater than about 20 V_{RMS}, and then lowered to be less than about 20 V_{RMS} when the plasma has been ignited and is operating as used for processing. Meanwhile, the impedance of the outer shield to ground may be made to be very low by directly grounding that shield or by use of a fixed capacitance in series to electrical ground so that the inductance of the circuit for grounding the outer part of the shield is cancelled by the fixed capacitance. In this case, when the inner layer voltage is high there can be sufficient capacitive coupling to the dielectric wall to ignite the plasma, but after ignition the capacitive coupling is reduced to a smaller value (e.g., less than 10 Volts, or less than 5 Volts) that is adequate for sustaining the plasma. In some embodiments, the outer layer 820 can be grounded during all periods of the processing, or in alternative embodiments can be allowed to float when the variable impedance for the inner layer 810 takes on a high value.

An automated computer control system can include one or more processors and one or more memory devices. The one or more processors can execute computer-readable instructions stored in the one or more processors to cause the one or more processors to perform operations. For instance, the one or more processors can provide control signals to various components (e.g., tunable reactance, paths to ground, RF power source, etc.) to control operation of a plasma processing apparatus.

These and other modifications and variations to the present invention may be practiced by those of ordinary skill in the art, without departing from the spirit and scope of the present invention, which is more particularly set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A plasma processing apparatus, comprising:
a plasma chamber;
a dielectric wall forming at least a portion of the plasma chamber;
an inductive coupling element located proximate the dielectric wall, the inductive coupling element configured to generate a plasma in the plasma chamber when energized with radio frequency (RF) energy; and
an electrostatic shield located between the inductive coupling element and the dielectric wall, the electrostatic shield comprising a plurality of shield plates, wherein a surface of each shield plate proximate the dielectric wall has at least one edge close to the dielectric wall rounded with a radius of greater than or equal to about 1 millimeter.

2. The plasma processing apparatus of claim 1, wherein a gap located between two neighboring shield plates of the electrostatic shield is in a range of about 2 millimeters to about 30 millimeters.

3. The plasma processing apparatus of claim 1, wherein a gap between the electrostatic shield and an outer surface of the dielectric wall is in a range of about 0.5 millimeters to about 15 millimeters.

4. The plasma processing apparatus of claim 1, wherein a thickness of each of the plurality of shield plates is in a range of about 2 millimeters to about 15 millimeters.

5. The plasma processing apparatus of claim 1, wherein a curvature radius of the at least one edge is in a range of about 1 millimeter to about 15 millimeters.

6. The plasma processing apparatus of claim 1, wherein the electrostatic shield is connected to an electrical ground through a variable impedance.

7. The plasma processing apparatus of claim 1, wherein the electrostatic shield comprises a first layer and a second layer, the first layer comprising a first plurality of shield plates and the second layer comprising a second plurality of shield plates, wherein each of the first and second plurality of shield plates has an elliptical cross-section or rounded cross-section.

8. The plasma processing apparatus of claim 7, wherein the first and second plurality of shield plates are arranged such that each gap between two neighboring shield plates of the first plurality of shield plates overlaps a shield plate of the second plurality of shield plates to obstruct a line of sight from the inductive coupling element to the dielectric wall.

9. The plasma processing apparatus of claim 7, wherein the first and second plurality of shield plates are independently connected to an electrical ground.

10. A plasma processing apparatus, comprising:
a plasma chamber;
a dielectric wall forming at least a portion of the plasma chamber;
an inductive coupling element located proximate the dielectric wall, the inductive coupling element configured to generate a plasma in the plasma chamber when energized with radio frequency (RF) energy; and
an electrostatic shield located between the inductive coupling element and the dielectric wall, the electrostatic shield comprising a plurality of slots, wherein each slot of the plurality of slots is angled relative to a direction perpendicular to the dielectric wall to produce an oblique line of sight angle from the inductive coupling element to the dielectric wall.

11. The plasma processing apparatus of claim 10, wherein each slot of the plurality of slots is angled at about 45°+/−15° relative to the direction perpendicular to the dielectric wall.

12. The plasma processing apparatus of claim 10, wherein each slot of the plurality of slots is angled in a clockwise direction to create a clockwise pattern between the electrostatic shield and the dielectric wall.

13. The plasma processing apparatus of claim 10, wherein each slot of the plurality of slots is angled in a counter-clockwise direction to create a counter-clockwise pattern between the electrostatic shield and the dielectric wall.

14. A plasma processing apparatus, comprising:
a plasma chamber;
a dielectric wall forming at least a portion of the plasma chamber;
an inductive coupling element located proximate the dielectric wall, the inductive coupling element configured to generate a plasma in the plasma chamber when energized with radio frequency (RF) energy; and
an electrostatic shield located between the inductive coupling element and the dielectric wall, the electrostatic shield comprising a plurality of shield plates, wherein each of the plurality of shield plates comprises a first part and a second part, the first part is in proximity to the dielectric wall and the second part is further away from the dielectric wall, wherein for any two neighboring shield plates of the plurality of shield plates, a first part of one shield plate overlaps a second part of other shield plate without contacting the second part to obstruct a line of sight from part of the inductive coupling element to the dielectric wall.

15. The plasma processing apparatus of claim 14, wherein each of the plurality of shield plates comprises at least one rounded edge.

16. The plasma processing apparatus of claim 14, wherein the plurality of shield plates are arranged in a clockwise outward direction.

17. The plasma processing apparatus of claim 14, wherein the plurality of shield plates are arranged in a counter-clockwise outward direction.

18. A plasma processing apparatus, comprising:
a plasma chamber;
a dielectric wall forming at least a portion of the plasma chamber;
an inductive coupling element located proximate the dielectric wall, the inductive coupling element configured to generate a plasma in the plasma chamber when energized with radio frequency (RF) energy; and
an electrostatic shield located between the inductive coupling element and the dielectric wall, the electrostatic shield comprising a first layer and a second layer, the first layer comprising a first plurality of shield plates and the second layer comprising a second plurality of shield plates, wherein the first and second plurality of shield plates are arranged such that each gap between two neighboring shield plates of the first plurality of shield plates overlaps a shield plate of the second plurality of shield plates to obstruct a line of sight from the inductive coupling element to the dielectric wall;
wherein one of the first layer and the second layer is connected to electrical ground through a low impedance and the other of the first layer and the second layer is connected to ground through a variable reactive impedance, the variable reactive impedance being adjustable by an automated control system such that the second plurality of shield plates have a voltage that is variable between a first voltage to ignite the plasma and a second voltage to sustain the plasma.

19. The plasma processing apparatus of claim 18, wherein the voltage is monitored by an RF voltage measurement circuit and the voltage is provided to the automated control system.

20. The plasma processing apparatus of claim 18, wherein the variable reactive impedance comprises an inductor in series with a variable capacitor and the voltage is set to be greater than about 20 Volts.
